(19) United States
(12) Patent Application Publication
(10) Pub. No.: US 2015/0156887 A1
(43) Pub. Date: Jun. 4, 2015

(54) METHOD OF FORMING AMORPHOUS ALLOY FILM AND PRINTED WIRING BOARD MANUFACTURED BY THE SAME

(71) Applicant: Samsung Electro-Mechanics Co., Ltd., Suwon-si (KR)

(72) Inventors: Ji Sung Cho, Suwon (KR); Toshiko Yokota, Suwon (KR); Makoto Dobashi, Suwon (KR); Jin Gu Kim, Suwon (KR); Ichiro Ogura, Suwon (KR); Je Hong Kyoung, Sungnam (KR)

(73) Assignee: Samsung Electro-Mechanics Co., Ltd., Suwon-si (KR)

(21) Appl. No.: 14/209,143

(22) Filed: Mar. 13, 2014

(30) Foreign Application Priority Data
Nov. 29, 2013 (KR) 10-2013-0147342

(51) Int. Cl. H05K 3/02; H05K 1/09

(52) U.S. Cl. CPC H05K 3/022; H05K 1/09; H05K 2201/0137; H05K 2201/032

(57) ABSTRACT

Disclosed herein are a method of forming an amorphous alloy film and a printed wiring board manufactured by the same. The amorphous alloy film may be formed on a copper foil as one of rust-proofing treatment methods of the copper foil to thereby simultaneously show and improve corrosion-resistance and conductivity, and the amorphous alloy film may be formed by the sputtering deposition method, such that high melting point materials may be manufactured as a thin film at a relatively low temperature and the amorphous alloy film having strong adhesion strength with a substrate may be obtained.

### CROSS REFERENCE(S) TO RELATED APPLICATIONS

This application claims the foreign priority benefit under 35 U.S.C. Section 119 of Korean Patent Application Serial No. 10-2013-0147342, entitled “Method of Forming Amorphous Alloy Film and Printed Wiring Board Manufactured by the Same” filed on Nov. 29, 2013, which is hereby incorporated by reference in its entirety into this application.

### BACKGROUND OF THE INVENTION

1. Technical Field

The present invention relates to a method of forming an amorphous alloy film using a sputtering deposition method and a printed wiring board manufactured by the same.

2. Description of the Related Art

Recently, in accordance with rapid development of IT technology, high performance, high functionalization, and miniaturization of electronic devices such as a portable terminal device, a computer, a display, and the like have rapidly progressed. Therefore, electronic components such as a semiconductor, and the like, usable in the electronic devices or a substrate for mounting the electronic components have also been required to have high density and high performance.

Due to the recent trend, a rust-proofing treatment of a copper foil used in a substrate is a significantly important process for preventing corrosion of a surface. An amorphous alloy film is formed on a copper foil as one of the rust-proofing treatment methods, wherein the formed amorphous alloy film has an electric bilayer configuration to provide corrosion-resistance. Corrosion-resistance based on the electric bilayer is shown by not forming a passivity film (a state in which a metal loses reactivity shown in a normal state) but forming a portion having high electrical resistance in a liquid-phase having a narrow range in the middle of the solid and liquid levels, on a rust-proofing surface of copper.

The amorphous alloy, which is referred to as a non-crystalline alloy, indicates an alloy having an irregular atom structure like liquid. The amorphous alloy is obtained by rapidly cooling a metal dissolved in manufacturing the alloy at a rate of 100 per 1 second, and has properties that are not shown in general alloys. Since the amorphous alloy does not have a crystalline structure even though being observed in a molecular unit, rigidity thereof is more excellent than that of general metal materials. In addition, a novel amorphous alloy generally manufactured by mixing zirconium with titanium, nickel, copper, and the like, has a smooth surface like liquid, such that the amorphous alloy is referred to as a liquid metal.

At the time of rust-proofing treatment of a copper foil according to the related art, a passivity film is formed on the rust-proofing surface of the copper, thereby providing corrosion-resistance. However, since the passivity film has excellent corrosion-resistance but is a strong insulator to provide weak conductivity, thereby not usable in an environment in which corrosion-resistance and conductivity are simultaneously required.

### RELATED ART DOCUMENT

### Patent Document

(Patent Document 1) Korean Patent Laid-Open Publication No. 10-2012-0027284

### SUMMARY OF THE INVENTION

An object of the present invention is to provide a method of forming an amorphous alloy film capable of simultaneously showing and improving corrosion-resistance and conductivity by forming an amorphous alloy film rather than a passivity film on a copper foil as one of rust-proofing treatment methods of the copper foil. Another object of the present invention is to provide an amorphous alloy film formed by a sputtering deposition method to manufacture high melting point materials such as molybdenum (Mo) and niobium (Nb) as a thin film at a relatively low temperature.

According to a first exemplary embodiment of the present invention, there is provided a method of forming an amorphous alloy film including: forming an insulating film on a support body; forming a copper thin film on the insulating film; and forming an amorphous alloy film on the copper thin film.

The insulating film may be any one heat-resistant polymer film selected from a polyimide (PI) a polvphenylene sulfide (PPS) film, a liquid crystal polymer (LCP) film, a fluorine film, and a polyethylene naphthalene (PEN) film.

The amorphous alloy may be two or more kinds of alloys selected from Cu, Ag, Zn, Au, Ni, Sn, Mo, Nb, and B.

The amorphous alloy may be a high melting point metal material allowing the insulating film having the copper thin film formed thereon to be maintained at a low temperature and being closely adhered on the copper thin film without pores under vacuum pressure in a sputtering apparatus.

The high boiling point amorphous alloy may be molybdenum (Mo) and niobium (Nb).

The amorphous alloy may contain copper (Cu) in a content of 40 to 70 at %, nickel (Ni) in a content of 20 to 30 at %, molybdenum (Mo), niobium (Nb), and boron (B).

According to a second exemplary embodiment of the present invention, there is provided a printed wiring board manufactured by the method of forming the amorphous alloy film as described above.

### BRIEF DESCRIPTION OF THE DRAWINGS

FIG. 1 shows a process flow chart of an exemplary embodiment of a method of forming an amorphous alloy film according to the present invention;

FIG. 2 is a schematic diagram of a sputtering apparatus for forming the amorphous alloy film of the exemplary embodiment of the present invention; and

FIG. 3 is a cross-sectional view of a printed wiring board manufactured by the exemplary embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. These embodiments may be provided so that this disclosure will be thorough and complete, and will fully convey the scope of the invention to those skilled in the art.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

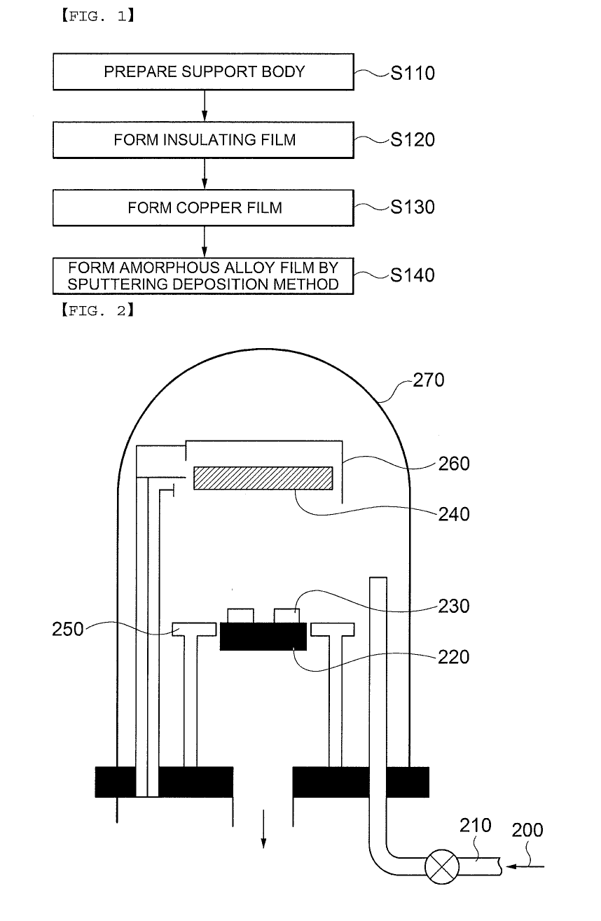

FIG. 1 shows a process flow chart of an exemplary embodiment of a method of forming an amorphous alloy film according to the present invention; and FIG. 3 is a cross-sectional view of a printed wiring board manufactured by the exemplary embodiment of the present invention.

Referring to FIGS. 1 and 3, the method of forming the amorphous alloy film according to the present embodiment may include preparing a support body S110, forming an insulating film on the support body S120, forming a copper thin film on the insulating film S130, and forming an amorphous alloy film on the copper thin film by a sputtering deposition method S140.

The support body 110 may be a substrate or a core made of an insulating material. In addition, the support body 110 may be used as a carrier at the time of manufacturing a printed wiring board, and a support means separated and removed after the printed wiring board is manufactured.

In the forming of the insulating film 120, a heat-resistance polymer film may be used as the insulating film for forming an insulating layer 120. The heat-resistance polymer film, which is a high performance polymer film having original advantages such as lightness, process easiness, and flexibility of polymer materials without changes in view of initial physical properties and dimensions in severe environment and situation, may be a polyimide (PI) film, a polyphenylene sulfide (PPS) film, a liquid polymer film (LCP), a fluorine film, a poly ethylene naphthalene (PEN) film, and the like, or may be a film showing an insulation property, but the present invention is not limited thereto.

A copper thin film 130 may be formed on the insulating film, wherein the copper thin film may be formed by a plating process. Since an electrolytic copper plating process by electrolysis is not performed at the time of plating a surface of the insulating film 120, an electroless copper plating process achieved by a precipitation reaction is firstly performed and then an electrolytic copper plating process is performed. The electroless copper plating process, which is a process of plating a surface of a nonconductor (an insulator), has a difficulty in thickening a plating film and has poor physical properties as compared to the electrolytic copper plating process. After the electroless copper plating process is performed, the electrolytic copper plating process may be performed using conductivity obtained by the electroless copper plating process, wherein the electrolytic copper plating process is easy to form a thickly coated plating film and has excellent physical properties of the film. Therefore, the electroless copper plating process is a primary plating process for the electrolytic copper plating process, which is performed as a pre-treatment process for smoothly progressing the electrolytic copper plating process and therefore, may not be used as it is, and a plating performance thereof may be supplemented by further performing the electrolytic copper plating process. As described above, the copper thin film 130 formed on the insulating film 120 may be formed so as to have the entire thickness of the printed wiring board and a thickness of 3 to 10 μm of the plating layer depending on a degree of fine patterning process.

In addition, an amorphous alloy film 140 may be formed on the copper thin film 130. The amorphous alloy film may be subjected to a sputtering deposition method, wherein an amorphous alloy is used in the sputtering deposition method. Representative examples of a method of forming an amorphous alloy film include a thermal spray method and a sputtering deposition method, and the sputtering deposition method is usually used. Hereinafter, a method of forming the amorphous alloy film by using the sputtering deposition method will be mainly described.

The amorphous alloy film is formed using the amorphous alloy, wherein the amorphous alloy may be two or more kinds of alloys selected from Cu, Ag, Zn, Au, Ni, Sn, Mo, Nb, and B, and among them, may contain copper (Cu) in a content of 40 to 70 at %, nickel (Ni) in a content of 20 to 30 at %, molybdenum (Mo), niobium (Nb), and boron (B). In addition, the amorphous alloy may be a high melting point metal material maintaining the insulating film having the copper thin film formed thereon at a low temperature and being closely adhered on the copper thin film without pores under vacuum pressure in a sputtering apparatus. Here, the high melting point amorphous alloy indicates molybdenum (Mo) and niobium (Nb).

The amorphous alloy film is formed in order that the copper thin film 130 simultaneously has corrosion-resistance and conductivity, and the corrosion-resistance and conductivity may be controlled by adjusting an alloy ratio in different kinds including copper (Cu) and nickel (Ni). Here, in the case in which chromium (Cr) is contained in the amorphous alloy, since a passivity film having high insulating property is formed due to a Cr oxide, causing a problem in conductivity, it is preferred that Cr is not contained in the amorphous alloy.

In addition, since metals such as molybdenum (Mo) and niobium (Nb) have high melting point of 2,610 and 2,740, respectively, it is difficult to melt the metals by other deposition methods rather than the sputtering deposition method. That is, among the thermal spray methods, an atmospheric plasma thermal spray method having the highest flame temperature of 10,000 to 15,000K is the only method of melting high melting point metals. However, since the atmospheric plasma thermal spray method is performed under atmospheric pressure, ambient air is mixed with the plasma jet flame, causing disadvantages, that is, porosity is increased and adhesion strength is weakened. Due to the above-described reasons, the sputtering deposition method is more preferred than the thermal spray method as a deposition method of molybdenum (Mo) and niobium (Nb). That is, by using the sputtering deposition method, high melting point materials may be manufactured as a thin film at a relatively low temperature and a uniform film in a large area may be obtained. In addition, since the sputtering deposition method is performed under a vacuum state without causing a chemical reaction, pores are not formed, such that a film having strong adhesion strength with a substrate may be obtained. Therefore, in the case of metals such as molybdenum (Mo) and niobium (Nb), it is preferred that the amorphous alloy film is formed by using the sputtering deposition method.

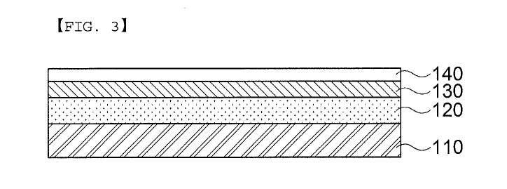

Meanwhile, a method of forming the amorphous alloy film using the sputtering deposition method and a process thereof will be described in detail with reference to FIG. 2.

FIG. 2 is a schematic diagram of a sputtering apparatus for forming the amorphous alloy film of the exemplary embodiment of the present invention.

Referring to FIG. 2, the process of forming the amorphous alloy film on the copper thin film using the sputtering deposition method of the present exemplary embodiment will be described in detail.

An inert gas (Group 18 element; 200) as a sputtering gas is injected into a chamber 270 where vacuum is maintained 210. In the case in which the sputtering gas is not an inert gas, since an undesired reaction in addition to the sputtering deposition may be caused, the inert gas having relatively less reactivity is injected to the chamber. Among the inert gases, an argon (Ar) gas is usually used. The reason is that helium (He), neon (Ne) in the same group as argon but having smaller weight than that of argon are excessively lighter than Ar, and krypton (Kr) or xenon (Xe) are materials that are not easily obtained.

In the case in which a direct-current power (about 1 W per cm²) is applied to a target 240 while supplying an argon (Ar) gas to a gas inlet 210, plasma between the copper thin film 230 formed by a plating process and the target is generated. The plasma, which is a fourth material state rather than general states including solid, liquid, and gas, is a state that a gas is separated into electrons and atomic nucleus at tens of thousands of by applying high energy in a gaseous state.

In the plasma state, argon (Ar) gas is ionized to positive ions, and Ar positive ions are accelerated to an anode 260 due to a DC ammeter and strongly collide on a surface of the target. In the case in which the collision energy is sufficiently large, since atoms are separated from the surface of the material (target) consisting of the anode, the atoms of the target are burst out from the surface to the outside, and stacked on the copper thin film formed by the plating process. The above-described process is a process of forming the amorphous alloy film by the sputtering deposition method.

An important factor in determining a structure of the amorphous alloy film formed as described above is a temperature of the substrate. Here, the substrate includes the copper thin film formed on the insulating film, wherein the substrate is positioned on a heater 220 and heat is applied thereto. In general, heating wires are provided with the back side of the substrate, such that temperature is controlled, and in many cases, a halogen heater having nichrome or tungsten heating wires is used. In the case of the sputtering deposition method, even though the temperature of the substrate is relatively low, the high melting point metals such as molybdenum (Mo) and niobium (Nb) may be manufactured as a thin film, and the amorphous alloy film may be formed by using properties of the alloy and using the sputtering deposition method rather than a thermal spray method as described in the present invention.

In addition, in the case in which the coated film is formed by the thermal spray method, a coated film having excellent corrosion-resistance, abrasion-resistance, heat-resistance, electrical insulation may be formed; however, has a limitation in depositing high melting point metals. The thermal spray method, which is a method that melted metals are sprayed and solidified on a surface of a metal product, a glass, or the like, and examples thereof include a flame thermal spray method, a detonation thermal spray method, a high velocity flame spray method, an arc thermal spray method, an atmospheric plasma spray method, and the like. In the case of the flame thermal spray method, the flame temperature is 3,000 to 3,350K, in the case of the detonation thermal spray method, the flame temperature is 4,500K and in the case of the high velocity flame spray method, the flame temperature is 3,170 to 3,440K, that is, the most of metals are melted in the thermal spray methods. However, since metals such as molybdenum (Mo) and niobium (Nb) have high melting points of 2,610 and 2,740 , respectively, the metals may be melted by using the atmospheric plasma thermal spray method only. The atmospheric plasma thermal spray method, which has the flame temperature of 10,000 to 15,000K, is an essential and unique spray method in which high melting point materials are capable of being melted.

However, since the atmospheric plasma thermal spray method capable of melting the high melting point metals is performed under atmospheric pressure, ambient air is mixed with the plasma jet flame, causing disadvantages, that is, porosity is increased and adhesion strength is weakened. A method of overcoming the above-mentioned disadvantages is the sputtering deposition method, and in the exemplary embodiment of the present invention, the sputtering deposition method is used to form the amorphous alloy film, such that the high melting point materials are also capable of being easily deposited on the metal thin film.

Hereinafter, a structure in which the amorphous alloy film is formed by using the sputtering deposition method will be described with reference to FIG. 3.

FIG. 3 is a cross-sectional view of a printed wiring board manufactured by the exemplary embodiment of the present invention.

As shown in FIG. 3, the printed wiring board of the present embodiment may include an insulating film 120 formed on a support body 110, a copper thin film 130 formed on the insulating film, and an amorphous alloy film 140 formed on the copper thin film by a sputtering deposition method.

The support body 110 may be a substrate or a core made of an insulating material. In addition, the support body 110 may be used as a carrier at the time of manufacturing a printed wiring board, and a support means separated and removed after the printed wiring board is manufactured.

The insulating film, which is a high performance polymer film, may be a polyimide (PI) film, a polyphenylene sulfide (PPS) film, a liquid crystal polymer (LCP) film, a fluorine film and a polyethylene naphthalene (PEN) film, or may be a film showing an insulation property, but the present invention is not limited thereto.

The copper thin film 130 may be formed by a plating process and have the entire thickness of the printed wiring board and a thickness of 3 to 10 μm of the plating layer depending on a degree of fine patterning process. During the sputtering deposition, the substrate (110 to 130 or 230) having a state in which the copper thin film is formed on the insulating film is manufactured, and atoms of a target are burst out and stacked to form the amorphous alloy film on the substrate.

The amorphous alloy film 140 may be a thin film and may be thinner than the copper thin film. A uniform film in a large area may be obtained and a film having strong adhesion strength with a substrate may be obtained by manufacturing high melting point metals such as molybdenum (Mo) and niobium (Nb) as a thin film.

The substrate including the formed amorphous alloy film may be useful in an environment simultaneously requiring corrosion-resistance and conductivity.

When manufacturing the amorphous alloy in order to more improve the corrosion-resistance, combination of the metal is considered. In view of corrosion-resistance against sulfuric acid having pH=1, niobium (Nb) is effective, and in the case in which niobium (Nb) is combined with molybdenum (Mo), the corrosion-resistance is more improved. In addition, in the case in which boron (B) is added to the Cu—Ni—Nb—Mo-based amorphous alloy formed as described above, the corrosion-resistance is more improved. Molybdenum (Mo) improves the corrosion-resistance in a reduction environment; however, an excessive amount of molybdenum (Mo) damages ductility, such that it is preferred to use an appropriate amount of molybdenum (Mo).

In order to improve conductivity, chromium (Cr) is not contained to the amorphous alloy. A chromium (Cr) oxide is easy to form passivity. The reason is that the passivity film has high insulating property, thereby not capable of providing desired conductivity in the present invention.

In the present embodiment, the amorphous alloy film is formed on the substrate 110 to 130 or 230, such that corrosion-resistance and conductivity may be simultaneously shown and ductility may be increased. When the amorphous alloy is manufactured, in the case in which a large amount of Mo and Nb are contained for corrosion-resistance, ductility is damaged, such that it is important that Nb is contained in a content of 8 to 10 at % and a content rate between Mo and B is balanced.

According to the present invention, the amorphous alloy film may be formed on the copper foil as one of the rust-proofing treatment methods of the copper foil to thereby simultaneously improve corrosion-resistance and conductivity of the copper foil.

In addition, the amorphous alloy film may be formed by the sputtering deposition method, such that the high melting point materials may be manufactured as the thin film at a relatively low temperature. Further, since the sputtering deposition is performed in the vacuum state, the pores are not formed, such that the amorphous alloy film having strong adhesion strength with the substrate may be formed.

Although the preferred embodiments of the present invention have been disclosed for illustrative purposes, those skilled in the art will appreciate that various modifications, additions and substitutions are possible, without departing from the scope and spirit of the invention as disclosed in the accompanying claims. Accordingly, such modifications, additions and substitutions should also be understood to fall within the scope of the present invention.

1. A method of forming an amorphous alloy film comprising:
forming an insulating film on a support body;
forming a copper thin film on the insulating film; and
forming an amorphous alloy film on the copper thin film by a sputtering deposition.

2. The method according to claim 1, wherein the insulating film is any one heat-resistant polymer film selected from a polyimide (PI) film, a polyphenylene sulfide (PPS) film, a liquid crystal polymer (LCP) film, a fluorine film and a polyethylene naphthalene (PEN) film.

3. The method according to claim 1, wherein the amorphous alloy is two or more kinds of alloys selected from Cu, Ag, Zn, Au, Ni, Sn, Mo, Nb, and B.

4. The method according to claim 1, wherein the amorphous alloy is a high melting point metal material allowing the insulating film having the copper thin film formed thereon to be maintained at a low temperature and being closely adhered on the copper thin film without pores under vacuum pressure in a sputtering apparatus.

5. The method according to claim 4, wherein the high boiling point amorphous alloy is molybdenum (Mo) and niobium (Nb).

6. The method according to claim 1, wherein the amorphous alloy contains copper (Cu) in a content of 40 to 70 at %, nickel (Ni) in a content of 20 to 30 at %, molybdenum (Mo), niobium (Nb), and boron (B).

7. A printed wiring board manufactured by the method of forming the amorphous alloy film according to claim 1.

8. A printed wiring board manufactured by the method of forming the amorphous alloy film according to claim 2.

9. A printed wiring board manufactured by the method of forming the amorphous alloy film according to claim 3.

10. A printed wiring board manufactured by the method of forming the amorphous alloy film according to claim 4.

11. A printed wiring board manufactured by the method of forming the amorphous alloy film according to claim 5.

12. A printed wiring board manufactured by the method of forming the amorphous alloy film according to claim 6.
